(19) United States
(12) Patent Application Publication
(10) Pub. No.: US 2005/0094563 A1
(43) Pub. Date: May 5, 2005

(54) Method and device for reproducing data

(76) Inventors: Fusayuki Takeshita, Kawasaki (JP); Kenichi Horio, Kawasaki (JP); Masahiko Murakami, Kawasaki (JP); Satoshi Okuyama, Kawasaki (JP); Hisayuki Sekine, Kawasaki (JP)

Correspondence Address: KATTEN MUCHIN ZAVIS ROSENMAN, 575 MADISON AVENUE, NEW YORK, NY, 10022-2585, US

(21) Appl. No.: 10/869,601

(22) Filed: Jun. 16, 2004

(30) Foreign Application Priority Data
Oct. 30, 2003 (JP) 2003-371217

(51) Int. Cl. G01R 31/08

(52) U.S. Cl. 370/235; 370/506

(57) ABSTRACT

A speech communication device includes a data receiver that receives data from other device. The received data is stored in a buffer. The amount of the data in the buffer is monitored at a predetermined timing. When the amount of data in the buffer exceeds a steady delay threshold, an action determining unit instructs reduction in the stored data, reduction of an initial storage amount, and reduction of an upper limit threshold (a substantial buffer capacity).

### BACKGROUND OF THE INVENTION

1) Field of the Invention

The present invention relates to a method and a device for reproducing data, received in packets, which may be audio data and/or moving image data, and reproduces (plays or replays) the data.

2) Description of the Related Art

It is quite common these days to transmit data in the form of packets on the networks (for example, the Internet). Although most of the networks were originally designed for communication of plain data, these days it is possible to transmit/receive audio data and/or moving image data.

In the packet transmission, however, time taken by each of the plurality of packets of the same data for traveling from origin to the destination may differ. In other words, some packets reach early and others are delayed. When reproducing real time conversation, it is necessary that the packets are received in appropriate time and appropriate order. Therefore, if some packets are delayed too much, the conversation gets interrupted.

One approach is to store a certain number of packets in a buffer and reproduce the data while retrieving packets from the buffer. However, there is produced a delay in the reproducing because the packets are first stored in the buffer. Such a delay increases with the buffer capacity. Therefore, how to decide the buffer capacity is an important issue.

Japanese Patent Application Laid-Open No. 2003-87317 discloses a technique in which amount of delay in the arrival of packets is measured and the buffer capacity is determined based on the delay. Japanese Patent Application Laid-Open No. H11-215182 discloses a technique in which packets are deleted after certain time when the buffer is full.

However, an apparatus that measures the arrival time is necessary in the technology disclosed in Japanese Patent Application Laid-Open No. 2003-87317. Moreover, the amount of data transmitted from the origin and that is received and reproduced at the destination has to be same. For example, if the amount of data transmitted from the origin is larger, the buffer gets overflowed at all times, and there is produced a steady reproduction delay. Even if packets are deleted from the buffer, the buffer again gets overflowed with new packets and the reproduction delay can not be stopped.

In other words, in the conventional technique, if the amount of data transmitted from the origin is larger than that reproduced at the destination, the buffer gets overflowed with the data and this results in a steady reproduction delay.

### SUMMARY OF THE INVENTION

It is an object of the present invention to solve at least the problems in the conventional technology.

A data reproducing device according to an aspect of the present invention is capable of performing packet communication and includes a receiving unit that receives data that is any one of audio data and moving image data or both by packet communication; a storage unit that stores the data received by the receiving unit; a monitoring unit that monitors a steady delay amount of the data based on an amount of data stored in the storage unit; and a determining unit that determines whether to delete data stored in the storage unit based on the steady delay amount monitored by the monitoring unit.

A method according to another aspect of the present invention is a method of reproducing data that is any one of audio data and moving image data or both and that is received in packet communication. The method includes receiving the data; storaging the received data; monitoring a steady delay amount of the data based on an amount of data stored; and determining whether to delete data stored in the storage unit based on the steady delay amount monitored.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a schematic in which a speech communication device, as a first embodiment of the data reproducing device according to the present invention, is connected to other speech communication device via a network;

FIG. 2 is a schematic for explaining relationship between buffer capacity and steady delay;

FIG. 3 is an exemplary configuration of a buffer shown in FIG. 1;

FIG. 4 is an exemplary configuration of a buffer controller shown in FIG. 1;

FIG. 5 is a flowchart of process procedure preformed by a reception and reproduction processor shown in FIG. 1;

FIG. 6 is a schematic for explaining relationship between a data storage amount and parameter setting of the buffer;

FIG. 7 is an explanatory diagram of a specific example of processing when the steady delay exists;

FIG. 8 is a schematic of the reception and reproduction processor at the time of monitoring the steady delay amount according to reproduction timing of received data;

FIG. 9 is a schematic of the reception and reproduction processor at the time of monitoring the steady delay amount according to time information output by a timer;

FIG. 10 is a schematic of the reception and reproduction processor that monitors the steady delay amount by using both of the time information output by the timer and data reception timing;

FIG. 11 is a schematic of the reception and reproduction processor that checks the validity and aligns the packets by using an RTP packet;

FIG. 12 is an explanatory diagram of an example in which the steady delay inspection period is calculated from the lowest storage amount at the time of last inspection;

FIG. 13 is an explanatory diagram of the configuration when the stored data is selectively deleted; and

FIG. 14 is an explanatory diagram of an example in which the detected steadily stored data is deleted collectively.

### DETAILED DESCRIPTION

Exemplary embodiments of a method and a device for reproducing data according to the present invention are explained below in detail, with reference to the accompanying drawings.

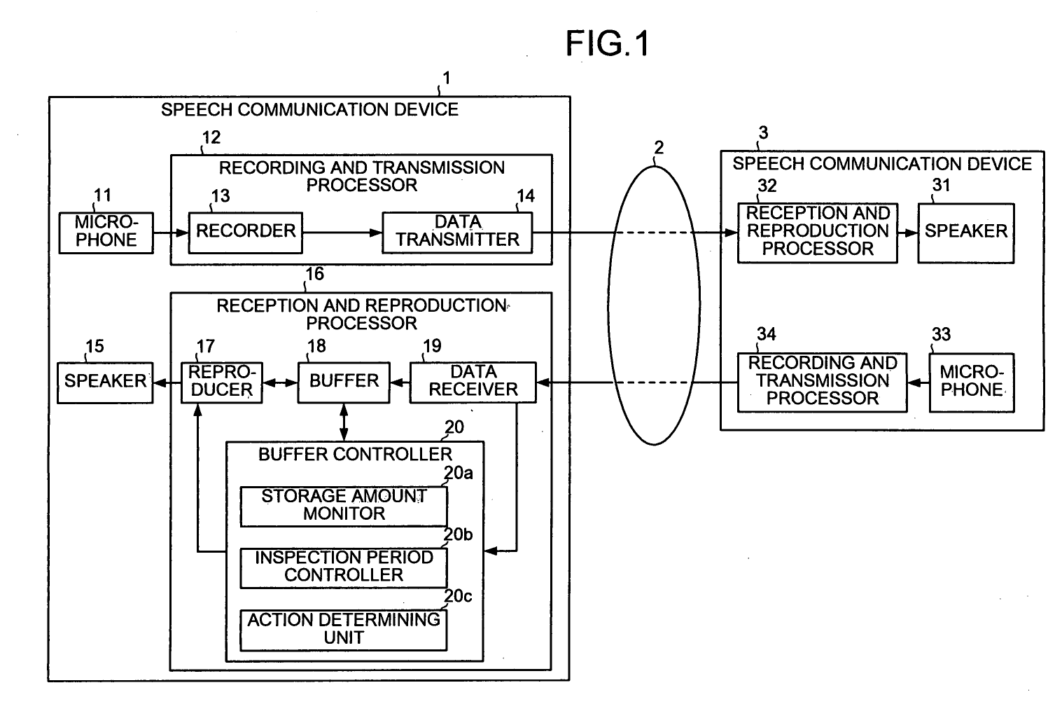

FIG. 1 is a schematic in which a speech communication device 1, as a first embodiment of the data reproducing device according to the present invention, is connected to other speech communication device 3 via a network 2. The network 2 is a packet communication network using the Internet Protocol (IP) protocol.

The speech communication device 1 has a microphone 11, a recording and transmission processor 12, a speaker 15, and a reception and reproduction processor 16 therein. Likewise, the speech communication device 3 has a microphone 33, a recording and transmission processor 34, a speaker 31, and a reception and reproduction processor 32 therein.

The speech communication device 1 transmits speech collected by the microphone 11 to the speech communication device 3 as packet data by the recording and transmission processor 12. The speech communication device 3 receives the packet data by the reception and reproduction processor 32 to reproduce the packet data to speech data, and outputs the speech data from the speaker 31. Likewise, the speech communication device 3 transmits speech collected by the microphone 33 to the speech communication device 1 as packet data by the recording and transmission processor 34. The speech communication device 1 receives the packet data by the reception and reproduction processor 16 to reproduce the packet data to speech data, and outputs the speech data from the speaker 15.

Therefore, the speech communication devices 1 and 3 can transmit and receive the speech data mutually, and realize speech conversation via the network 2. The reception and reproduction processor 16 of the speech communication device 1 will be specifically explained below, but the configuration is also applicable to the reception and reproduction processor 32.

The reception and reproduction processor 16 has a reproducer 17, a buffer 18, a data receiver 19, and a buffer controller 20 therein.

The data receiver 19 outputs packet data received from the speech communication device 3 to the buffer 18, and informs the buffer controller 20 of the reception of the packet data. The buffer 18 temporarily stores the packet data received by the data receiver 19. The reproducer 17 reads out the data stored in the buffer 18 to reproduce the data to a speech signal, and outputs the speech signal from the speaker 15.

The buffer controller 20 is a processor that controls the storage amount in the buffer 18, to instruct execution and suspension of reproduction by the reproducer 17, and has a storage amount monitor 20a, an inspection period controller 20b, and an action determining unit 20c therein. The storage amount monitor 20a monitors the data storage amount in the buffer 18, and inspects the amount of steady delay at an inspection timing specified by the inspection period controller 20b. The action determining unit 20c determines the action to be executed by the buffer 18 and the reproducer 17, based on the data storage amount in the buffer 18 and the amount of steady delay, and gives instructions to the buffer 18 and the reproducer 17.

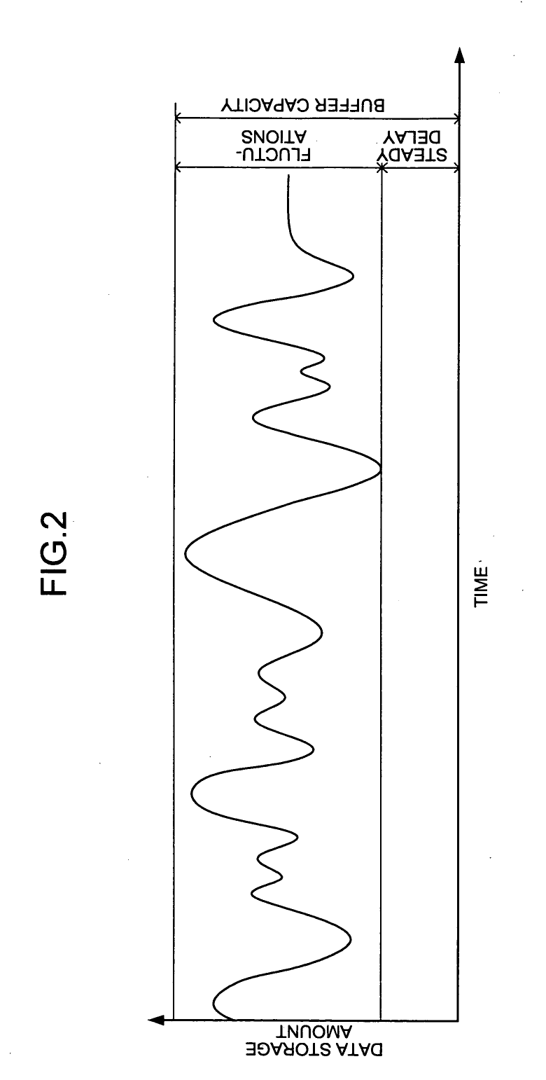

The relation between the buffer capacity and the steady delay will be explained with reference to FIG. 2. FIG. 2 is an explanatory diagram of the relation between the buffer capacity and the steady delay. As shown in this drawing, the data storage amount in the buffer 18 varies according to the fluctuations in reception delay of the packet data. Further, the buffer 18 also stores data of the steadily stored steady delay.

Therefore, the buffer 18 requires the capacity for storing the steady delay and the fluctuations in reception delay. Here, if the buffer for the fluctuations in reception delay is reduced, when receiving a packet having a large delay, reproduction is interrupted. Therefore, it is required to ensure an appropriate capacity, but the steady delay becomes a cause of fixed reproduction delay, and hence it is desired to reduce it.

The speech communication device 1 therefore inspects the amount of steady delay at the inspection timing specified by the inspection period controller 20b, and when the steady delay occurs, the data stored in the buffer 18 is deleted to reduce the reproduction delay.

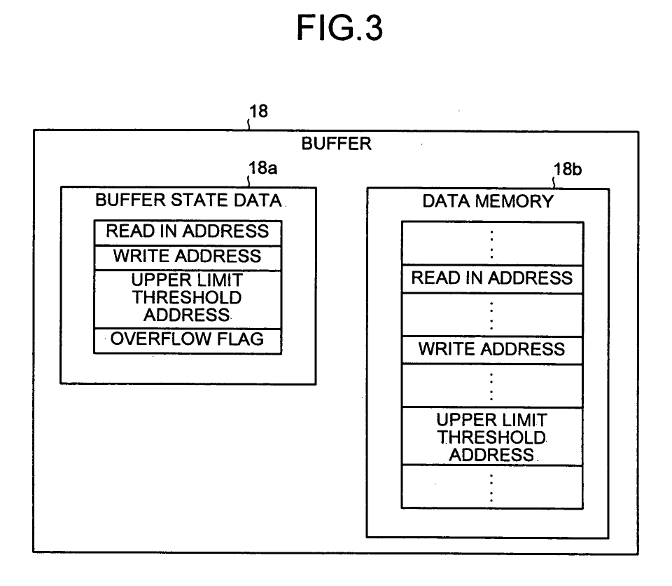

Specifically, as shown in FIG. 3, the buffer 18 has buffer state data 18a and a data memory 18b. The data memory 18b is a storage unit that stores the packet data, and the buffer state data 18a stores a “read in address”, a “write address”, an “upper limit threshold address”, and an “overflow flag” therein.

The “read in address” is an address indicating that read in of the data by the reproducer 17 has finished up to that address. The “write address” is an address indicating that data has been stored up to that address. The “upper limit threshold address” is an address indicating the upper limit of the data storage.

The data received by the data receiver 19 is written starting from the “write address”, and the position of the “write address” is shifted by as much as the written data. If the write address exceeds the “upper limit threshold address” by the write, the data for the excess amount is deleted, and the value of the “overflow flag” is set to “1”. The “overflow flag” is a flag indicating that an overflow has occurred in the buffer 18.

When data read is performed by the reproducer 17, the “read in address” is shifted to the range where the read in has finished, and the “upper limit threshold address” is shifted by as much as the read data. Therefore, in the data memory 18b, the data from the “read in address” to the “upper limit threshold address” becomes a certain size. Further, the data from the “read in address” to the “upper limit threshold address” is stored in the buffer and hence, becomes the substantial buffer capacity.

When the “upper limit threshold address” is shifted to the last address of the data memory 18b, the “upper limit threshold address” is shifted to the first address of the data memory 18b. Similarly, when the “write address” is shifted to the last address of the data memory 18b, the “write address” is shifted to the first address of the data memory 18b. That is, the data memory 18b has a virtual ring structure.

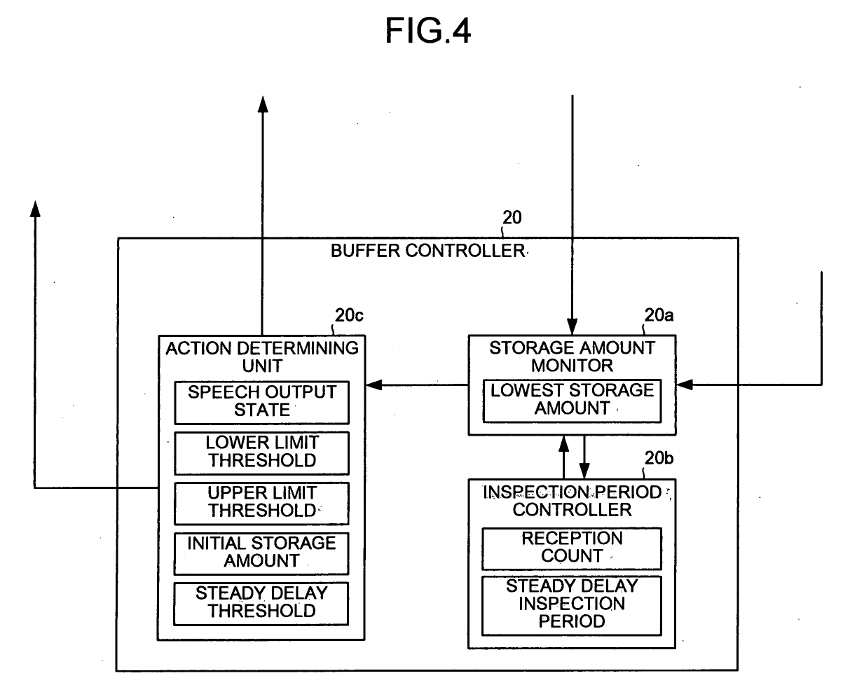

The specific configuration of the buffer controller 20 will be explained with reference to FIG. 4. As shown in this drawing, the storage amount monitor 20a stores a “lowest storage amount” therein. When notified of reception of data from the data receiver 19, the storage amount monitor 20a outputs the notification to the inspection period controller 20b, and obtains the data storage amount from the buffer 18.

Here, the data storage amount refers to a difference between the “read in address” and the “write address” in the data memory 18b. The storage amount monitor 20a outputs the obtained data storage amount to the action determining unit 20c, and compares the obtained data storage amount with the “lowest storage amount”, and when the obtained data storage amount falls below the “lowest storage amount”, updates the “lowest storage amount”.

The inspection period controller 20b stores a “reception count” and a “steady delay inspection period” therein. When notified of reception of data from the storage amount monitor 20a, the inspection period controller 20b increases the value of the “reception count” by one. Further, when the value of the “reception count” reaches a value specified as the “steady delay inspection period”, the inspection period controller 20b notifies the storage amount monitor 20a of this fact, and resets the value of the “reception count”.

When having received the notification from the inspection period controller 20b, the storage amount monitor 20a outputs the value of the “lowest storage amount” to the action determining unit 20c, and resets the value of the “lowest storage amount”. In other words, in this configuration, the “lowest storage amount” of the received data is inspected at an interval specified as the “steady delay inspection period”, and the “lowest storage amount”, that is, the amount of steady delay in the predetermined period is monitored according to the reception timing.

The action determining unit 20c stores therein a “speech output state”, a “lower limit threshold”, an “upper limit threshold”, an “initial storage amount”, and a “steady delay threshold” therein. The “speech output state” is a flag indicating whether reproduction of speech by the reproducer 17 is currently performed, and takes a value of “1” when reproduction is being performed, or a value of “0” when reproduction is not being performed.

When the stored data amount output by the storage amount monitor 20a reaches the “initial storage amount”, the action determining unit 20c allows the reproducer 17 to start reproduction of speech. When the stored data amount output by the storage amount monitor 20a falls below the “lower limit threshold”, the action determining unit 20c allows the reproducer 17 to stop reproduction, and increases the “initial storage amount” by a predetermined amount.

When the stored data amount output by the storage amount monitor 20a falls below the “lower limit threshold”, and when the value of the “overflow flag” is “1”, the action determining unit 20c increases the “upper limit threshold” by a predetermined amount, and outputs a new “upper limit threshold” to the buffer 18. When the action determining unit 20c changes the “upper limit threshold”, the buffer 18 updates the “upper limit threshold address” according to the changed value. That is, the substantial capacity of the buffer 18 increases due to an increase in the “upper limit threshold”.

When the “lowest storage amount” output by the storage amount monitor 20a exceeds the “steady delay threshold”, the action determining unit 20c deletes the data stored in the data memory 18b by a certain amount, and decreases the “upper limit threshold” and the “initial storage amount” respectively by a predetermined amount. In other words, when there is the steady delay, the data is deleted, and suppression of interruption in speech and reduction in reduction delay are realized by decreasing the data amount to be stored until starting reproduction, and the buffer capacity.

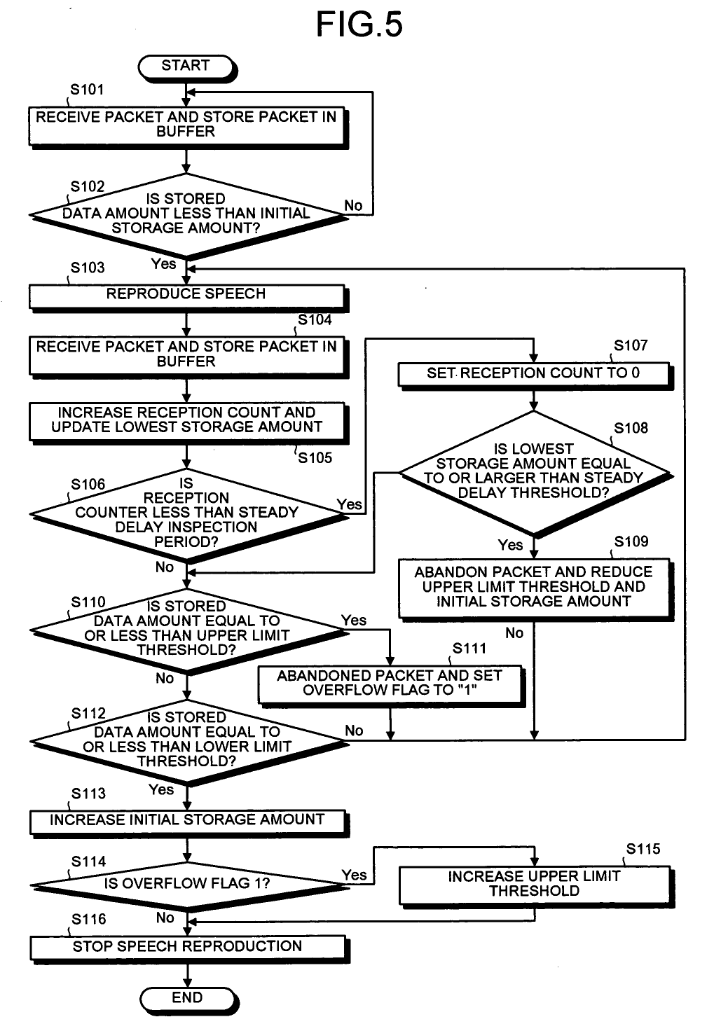

The processing operation of the reception and reproduction processor 16 will be explained. FIG. 5 is a flowchart for explaining the processing operation of the reception and reproduction processor 16. This flowchart depicts a flow starting from the reproduction-suspended state. At first, the data receiver 19 receives packet data, and stores the data in the buffer 18 (step S101). Thereafter, the stored data amount is compared with the initial storage amount (step S102). When the stored data amount is less than the initial storage amount (step S102, No), the data receiver 19 executes reception of the packet data and stores the data again (step S101).

On the other hand, when the stored data amount becomes equal to or larger than the initial storage amount (step S102, Yes), reproduction of speech by the reproducer 17 is started (step S103). Thereafter, the data receiver 19 receives the next packet data and stores the data in the buffer 18 (step S104). The reception count is increased, to update the lowest storage amount (step S105).

As a result, when the reception count reaches the steady delay inspection period (step S106, Yes), the value of the reception count is set to “0” (step S107), to compare the lowest storage amount with the steady delay threshold (step S108).

When the lowest storage amount is equal to or larger than the steady delay threshold (step S108, Yes), the packet is abandoned, and the upper limit threshold and the initial storage amount are both reduced (step S109), to continue reproduction of speech (step S104).

On the other hand, when the reception count does not reach the steady delay inspection period (step S106, No), and the lowest storage amount is less than the steady delay threshold (step S108, No), it is determined whether the stored data amount is equal to or less than the upper limit threshold (step S110).

When the stored data amount is equal to or less than the upper limit threshold (step S110, Yes), the packet is abandoned, the overflow flag is set to “1” (step S11l), and reproduction of speech is continued (step S103).

On the other hand, when the stored data amount is less than the upper limit threshold (step S110, No), the stored data amount is compared with the lower limit threshold (step S112). As a result, when the stored data amount exceeds the lower limit threshold (step S12, No), reproduction of speech is continued (step S103).

On the other hand, when the stored data amount is equal to or less than the lower limit threshold (step S112, Yes), the initial storage amount is increased (step S113). Thereafter, if the value of the overflow flag is “1” (step S114, Yes), the upper limit threshold is increased (step S115).

When the value of the overflow flag is not “1” (step S114, No), or after an increase of the upper limit threshold (step S115), speech reproduction by the reproducer 17 is stopped (step S116), and the processing is finished. After the processing is finished, when the packet data is received, the processing is started again from step S101.

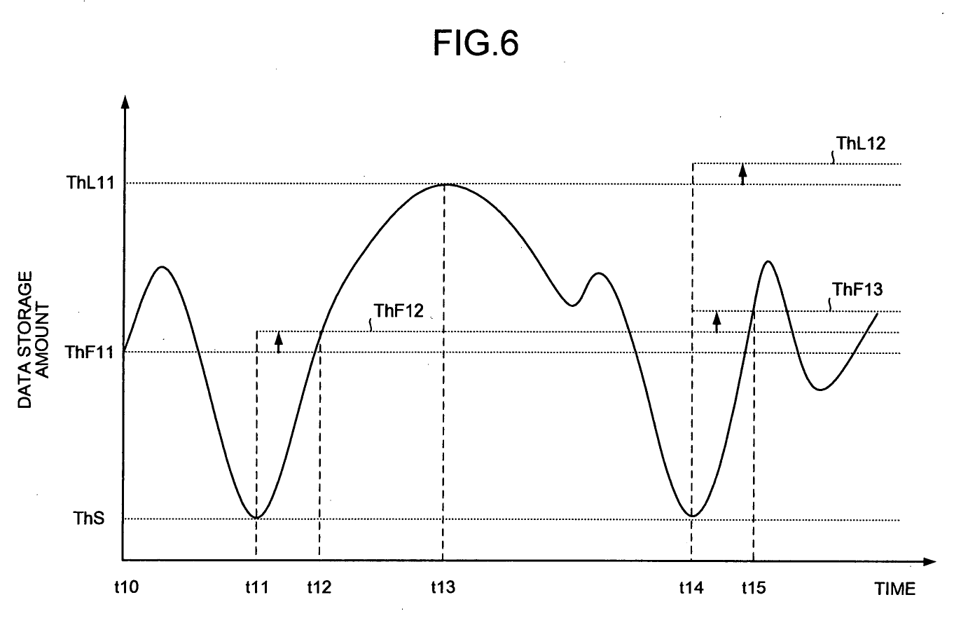

The specific example of processing by the reception and reproduction processor 16 will be explained below. FIG. 6 is an explanatory diagram of the relation between the data storage amount and parameter setting of the buffer 18. In this drawing, time t10 is the time at which the data storage amount reaches the initial storage amount ThF11, and reproduction of speech is started at this time t10.

The data storage amount then changes with the passage of time, and becomes the lower limit threshold ThS at time t11. As a result, reproduction of speech is suspended, and the initial storage amount increases to ThF12. Therefore, at the point when the data is stored and reaches the initial storage amount ThF12, reproduction of speech is resumed. Since overflow does not occur between time t10 to time t11, the upper limit threshold ThL11 does not change.

After reproduction of speech is resumed at time t12, the data storage amount reaches the upper limit threshold ThL11 at time t13. Therefore, data exceeding the upper limit threshold ThL11 is abandoned, and the overflow flag is set to “1”.

The data storage amount then becomes the lower limit threshold ThS again at time t14. As a result, reproduction of speech is suspended, and the initial storage amount further increases to ThF13. Since the overflow flag is set to “1” at time t13, the upper limit threshold increases to ThL12. At this time, the overflow flag is reset.

Therefore, when the data is stored next, and reaches the initial storage amount ThF13, reproduction of speech is resumed.

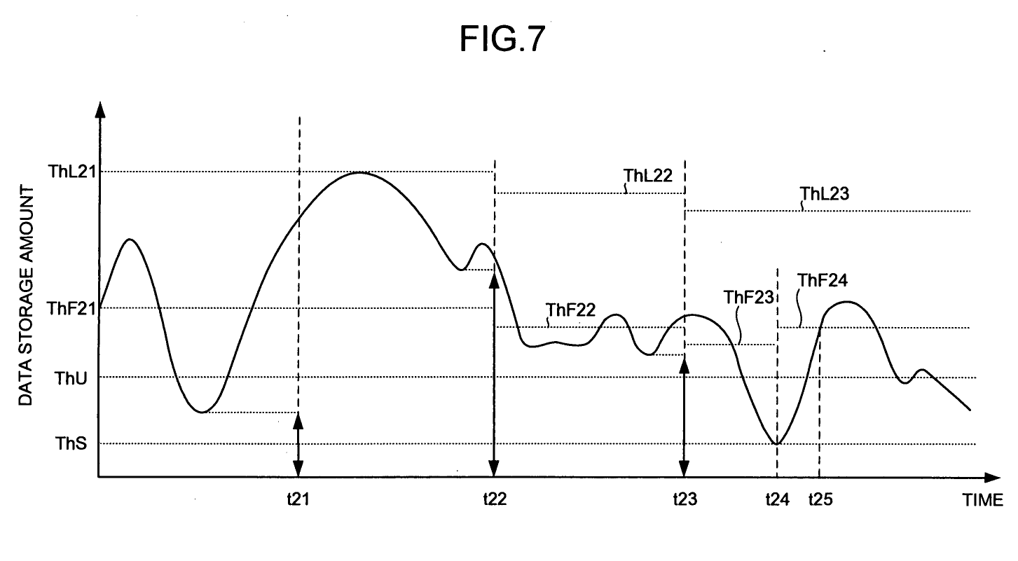

A specific example of processing when the steady delay exists will be explained with reference to FIG. 7. In this drawing, time t20 is the time at which the data storage amount reaches the initial storage amount ThF21, and reproduction of speech is resumed at time t20.

Then, the data storage amount changes with the passage of time. At this time, the storage amount monitor 20a monitors the lowest storage amount, and the inspection period controller 20b calculates the reception count. As a result, at time t21 when the value of the reception count reaches the steady delay inspection period, the action determining unit 20c compares the lowest storage amount with the steady delay threshold.

At time t21, since the lowest storage amount falls below the steady delay threshold ThU, the upper limit threshold ThL21 and the initial storage amount ThF21 are not updated. After the time t21, the data storage amount further changes, and monitoring of the lowest storage amount by the storage amount monitor 20a and calculation of the reception count by the inspection period controller 20b are continued.

At time t22 when the value of the reception count reaches the steady delay inspection period, the comparison between the lowest storage amount and the steady delay threshold is performed again. The lowest storage amount from time t21 to time t22 exceeds the steady delay threshold ThU. Therefore, the upper limit threshold ThL21 is decreased by a predetermined amount to ThL22, and the initial storage amount ThF21 is decreased by a predetermined amount to ThF22.

Similarly, between time t22 to time t23 when the value of the reception count reaches the steady delay inspection period, the data storage amount constantly exceeds the steady delay threshold ThU. Therefore, at time t23, the upper limit threshold ThL22 is further decreased to ThL23, and the initial storage amount ThF22 is further decreased to ThF23.

Then, at time t24, the data storage amount becomes the lower limit threshold ThS. Hence, reproduction of speech is suspended, and the initial storage amount is increased from ThF23 to ThF24. Therefore, it is at time t25 when the data is stored, and reaches the initial storage amount ThF12 that reproduction of data is resumed. At time t24, when the overflow flag is set to “1”, the upper limit threshold is increased from ThL23, and if the overflow flag is set to “0”, ThL23 is used as the upper limit threshold.

According to the speech communication device of the first embodiment, the lowest storage amount of the received data is monitored at an inspection timing specified by the inspection period controller, and when the lowest storage amount exceeds the steady delay threshold, reduction of the stored data, reduction of the initial storage amount, and reduction of the upper limit threshold (substantial buffer capacity) are performed. As a result, reproduction interruption in the reproducer 17 can be suppressed, reproduction delay can be suppressed to the minimum, and the occurrence of steady delay can be suppressed.

The application of the present invention is not limited to the configuration according to the first embodiment, and various kinds of application are possible. In a second embodiment, various examples of application of the speech communication device shown in the first embodiment will be explained.

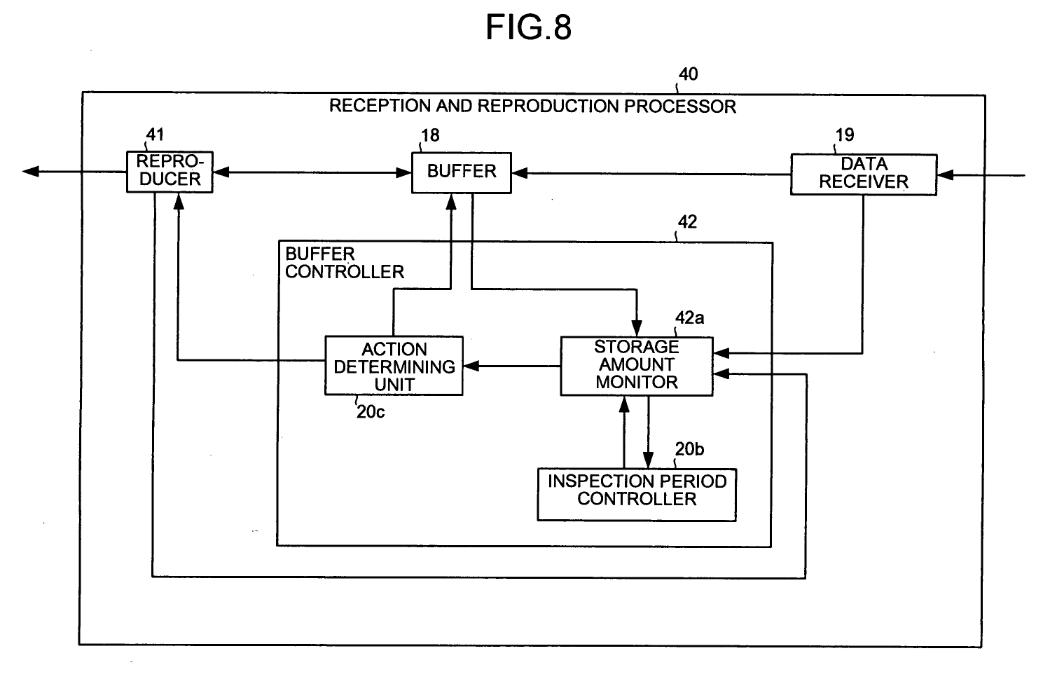

In the speech communication device according to the first embodiment, the lowest storage amount (steady delay) is inspected according to the reception timing of the packet data, but the lowest storage amount may be inspected according to the elements other than the data reception timing. FIG. 8 is a schematic of the reception and reproduction processor that monitors the steady delay amount according to the reproduction timing of the received data.

As shown in this drawing, a reception and reproduction processor 40 has a reproducer 41 and a buffer controller 42 therein. The other configuration and operation are the same as in the speech communication device 1 according to the first embodiment. Therefore, like reference signs designate like parts throughout, and the drawing and the explanation thereof are omitted.

The reproducer 41 reads out and reproduces the stored data in the buffer 18, and at the time of completion of reproduction of the read data, notifies the buffer controller 42 of the completion of reproduction. A storage amount monitor 42a in the buffer controller 42 outputs the lowest storage amount to the action determining unit 20c at the time of receiving the notification of reproduction completion, and resets the lowest storage amount. In other words, in this configuration, the “lowest storage amount” of received data, that is, the amount of steady delay in a predetermined period is monitored, according to the timing at which the data reproduction has been completed, as well as according to an interval specified as the “steady delay inspection period”. The configuration may obviously be such that the steady delay amount is inspected only at the time of completion of reproduction, without performing inspection at the data reception timing.

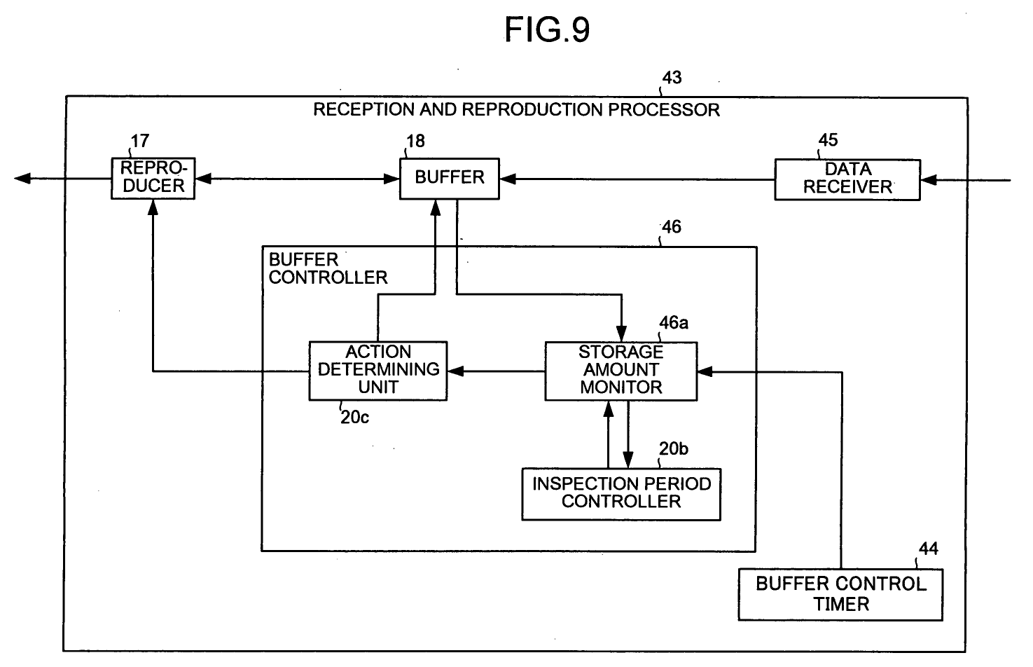

FIG. 9 is a schematic of the reception and reproduction processor that monitors the steady delay amount according to time information output by a timer provided for measuring the passage of time.

As shown in this drawing, a reception and reproduction processor 43 has a data receiver 45, a buffer control timer 44, and the buffer controller 42 therein. The other configuration and operation are the same as in the speech communication device 1 according to the first embodiment. Therefore, like reference signs designate like parts throughout, and the drawing and the explanation thereof are omitted.

The buffer control timer 44 outputs time information to the buffer controller 46 at a predetermined time interval. Since the data receiver 45 does not notify reception of data, a storage amount monitor 46a in the buffer controller 46 counts the time information output by the buffer control timer 44, to determine the output timing of the lowest storage amount. That is, in this configuration, the steady delay amount is monitored according to the time information output by the buffer control timer 44.

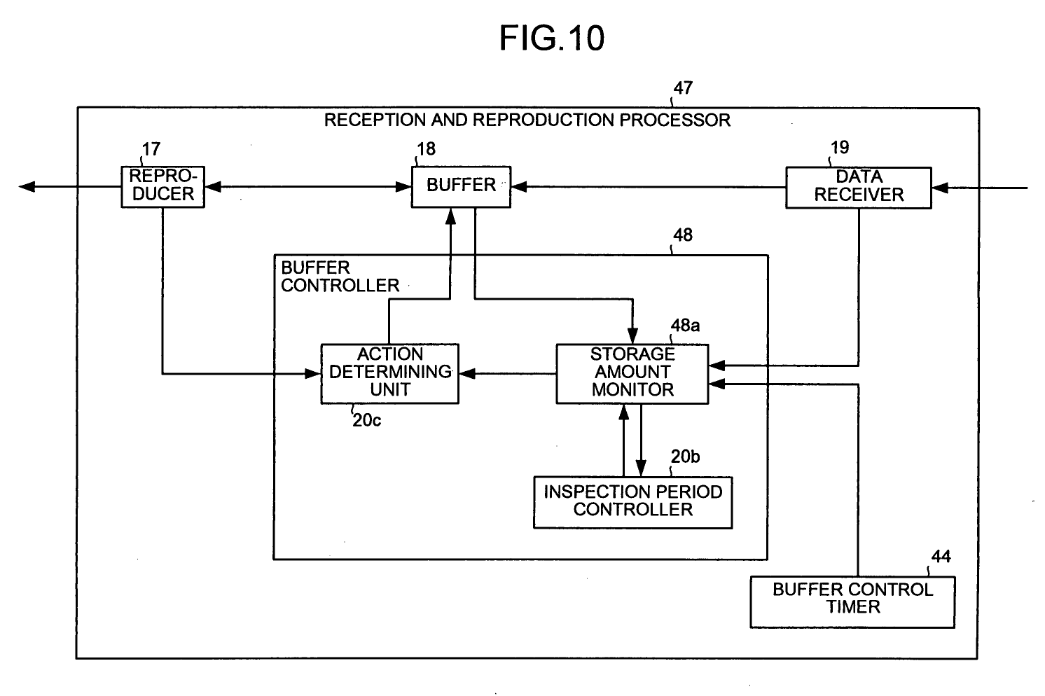

The steady delay may be monitored by using both of the time information output by the buffer control timer 44 and the data reception timing. FIG. 10 is a schematic of the reception and reproduction processor that monitors the steady delay amount by using both of the time information output by the timer and the data reception timing.

As shown in this drawing, a reception and reproduction processor 47 has the buffer control timer 44 and a buffer controller 48. The other configuration and operation are the same as in the speech communication device 1 according to the first embodiment. Therefore, like reference signs designate like parts throughout, and the drawing and the explanation thereof are omitted.

The buffer control timer 44 outputs the time information to the buffer controller 48 at a predetermined time interval. A storage amount monitor 48a in the buffer controller 48 uses the time information output by the buffer control timer 44 and the data reception notification from the data receiver 19 to determine the output timing of the lowest storage amount. That is, in this configuration, both of the time information output by the buffer control timer 44 and the data reception timing are used to monitor the steady delay amount.

In the packet communication, reception of an illegal packet may occur, or the reception sequence may be out of order due to fluctuations in reception delay. Therefore, when the packet data is received, it is desired to check the validity of the packet and align the packet sequence. As the technique for checking the validity of the packet and aligning the packets, there is a technique for transmitting and receiving a real time transport protocol (RTP) packet.

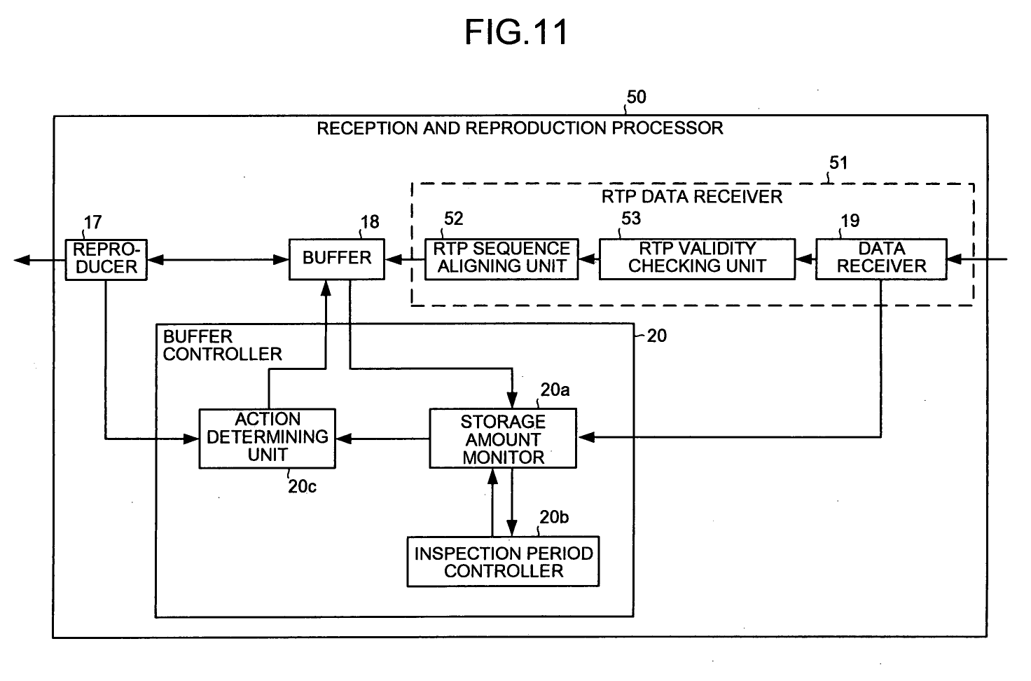

FIG. 11 is a schematic of the reception and reproduction processor that checks the validity and aligns the packets by using the RTP packet. As shown in this drawing, a reception and reproduction processor 50 has an RTP sequence aligning unit 52 and an RTP validity checking unit 53, and the RTP sequence aligning unit 52, the RTP validity checking unit 53, and the data receiver 19 constitute an RTP data receiver 51. The other configuration and operation are the same as in the speech communication device 1 according to the first embodiment. Therefore, like reference signs designate like parts throughout, and the drawing and the explanation thereof are omitted.

The RTP validity checking unit 53 checks the validity of the packet from RTP header information in the packet data received by the data receiver 19, and when the packet is valid, transmits the packet to the RTP sequence aligning unit 52, and when the packet is invalid, abandons the packet. The RTP sequence aligning unit 52 refers to the sequence number in the RTP header information in the received RTP packet data to check whether the packets are received in the right sequence, and if the sequence is reversed, aligns the packets in the right sequence and transmits the aligned packets to the buffer 18. The processing and operation after the buffer 18 receives the data are the same as in the first embodiment. By using the RTP in this manner, speech reproduction can be executed more accurately.

In the configuration shown in FIG. 11, when the data receiver 19 receives the data, data reception is notified to the storage amount monitor 20a, but data reception may be notified to the storage amount monitor 20a, for example, after the RTP validity checking unit 53 checks the validity of the packet, or after the RTP sequence aligning unit 52 aligns the packets.

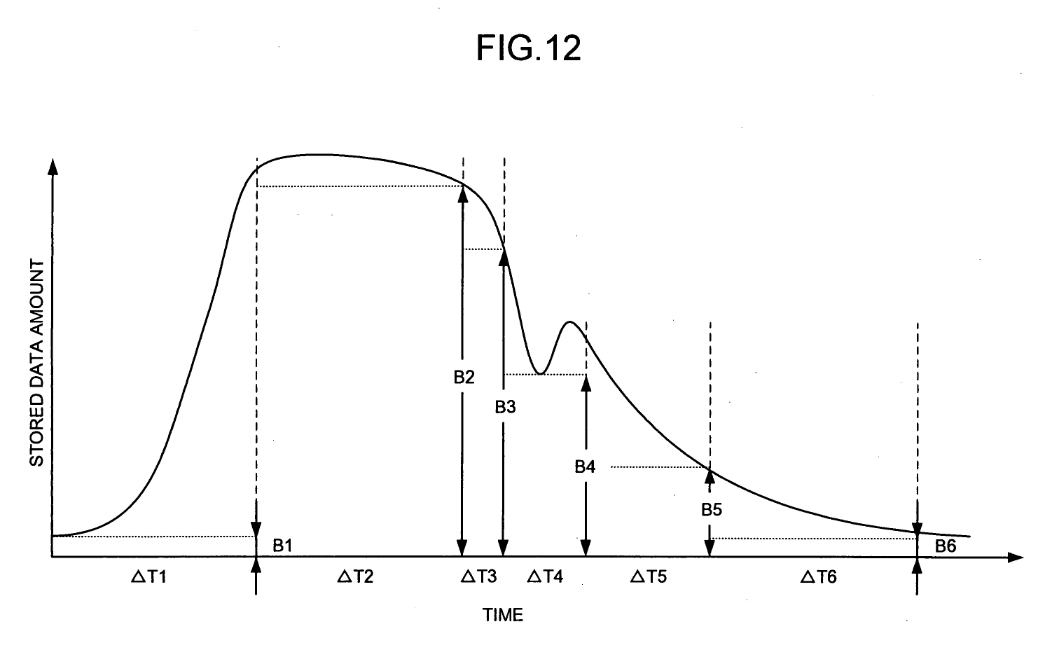

An example in which the steady delay inspection period is dynamically set from the past storage amount will be explained below. FIG. 12 is an explanatory diagram of an example in which the steady delay inspection period is calculated from the lowest storage amount at the time of last inspection, and reset. In this drawing, the steady delay inspection period is calculated from the following equation:
ΔTk=α/B(k−1),
wherein ΔTk denotes a k-th steady delay inspection period, Bk denotes the lowest storage amount in the k-th steady delay inspection period, and α denotes a constant.

Therefore, in FIG. 12, the second steady delay inspection period ΔT2 is obtained from the lowest storage amount B1 in the first steady delay inspection period ΔT1, and since the value of the lowest storage amount B1 is small, the steady delay inspection period ΔT2 becomes long. On the other hand, the third steady delay inspection period ΔT3 is obtained from the lowest storage amount B2 in the second steady delay inspection period ΔT2, and since the value of the lowest storage amount B2 is large, the steady delay inspection period ΔT3 becomes short. Thereafter, the fourth to the sixth steady delay inspection periods ΔT4 to ΔT6 are obtained respectively from the lowest storage amounts B3 to B5 in the third to the fifth steady delay inspection periods ΔT3 to ΔT5.

In this manner, the steady delay can be quickly reduced by dynamically setting the steady delay inspection period from the past storage amount.

When the steady delay or an overflow occurs, the stored data is deleted. When this deletion is performed, reduction in the stored data amount becomes possible without damaging the audibility at the time of reproduction, by deleting data closer to silence, of the stored data.

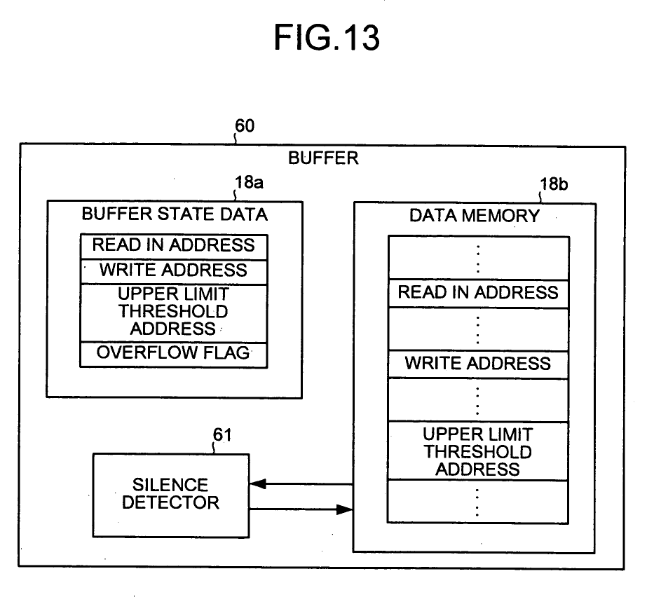

Thus, when the stored data is selectively deleted, as shown in FIG. 13, a silence detector 61 may be provided in a buffer 60. When the steady delay or overflow occurs, the silence detector 61 scans the contents of data (stored data) between the “read in address” and the “write address” in the data memory 18b, and selects data determined to be closer to silence. Thereafter, the selected data is deleted, and after the data is copied so that the memory area where the deleted data exists is filled, the “write address” is returned by the amount of deleted data.

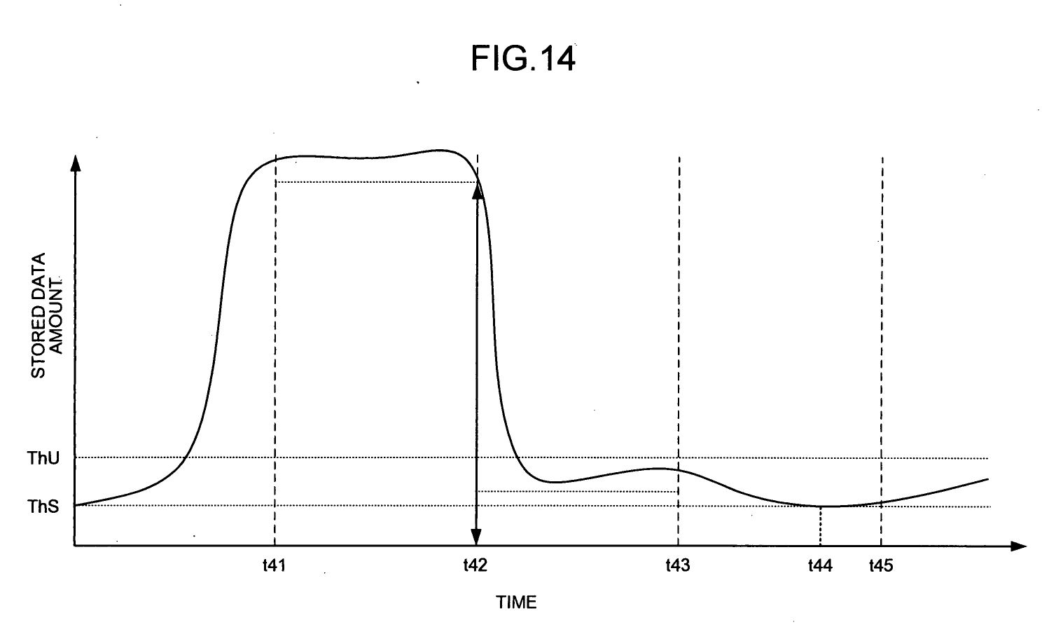

With regard to data deletion at the time of occurrence of the steady delay, in the first embodiment, a specified amount of data is deleted at the time of detection of the steady delay. However, all of the detected steadily stored data may be deleted at a time. FIG. 14 is an explanatory diagram of an example in which the detected steadily stored data is deleted collectively.

In this drawing, the lowest storage amount detected between time t41 to time t42, being the steady delay inspection period, is collectively deleted. Therefore, the steady delay can be reduced in a short period of time, as compared with when the specified amount is deleted. When the steady delay is collectively deleted, it is necessary to watch out so that the stored data does not fall below the lower limit threshold (underflow does not occur).

When the present invention is applied, the inspection timing of the steady delay can be set by using various types of information, such as completion of speech reproduction and time information by the timer. Further, by using the RTP, the packet can be received more accurately. By using the history of data storage amount to dynamically set the inspection period of steady delay, the steady delay can be reduced more quickly. By determining the data to be deleted based on the contents of the stored data, the data storage amount can be reduced without imparting the sense of incompatibility to the user, and the steady delay can be settled in short time, by collectively deleting the data corresponding to the steady delay, at the time of occurrence of steady delay.

The application of the present invention is not limited to the first and the second embodiments, and different embodiments are possible. For example, speech communication is explained in the first and the second embodiments, but the present invention is applicable to various types of communication highly requiring a real time operation such as moving images.

According to the present invention, the data reproducing device stores received data to monitor the steady delay amount from the storage amount, and determines whether to delete the stored data according to the monitoring result. As a result, a data reproducing device can be obtained, that can suppress reproduction interruption, the reproduction delay to the minimum, and the occurrence of steady delay, in the real time communication using the packet communication network.

Moreover, the data reproducing device stores received data to monitor the steady delay amount according to the reception timing, and determines whether to delete the stored data according to the monitoring result. As a result, a data reproducing device can be obtained, that can suppress reproduction interruption, the reproduction delay to the minimum, and the occurrence of steady delay with a simple configuration.

Furthermore, the data reproducing device stores received data to monitor the steady delay amount according to the data reproduction timing, and determines whether to delete the stored data according to the monitoring result. As a result, a data reproducing device can be obtained, that can effectively realize suppression of reproduction interruption, reduction in reproduction delay, and suppression of the occurrence of steady delay.

Moreover, the data reproducing device stores received data to monitor the steady delay amount according to the time information output by a timer, and determines whether to delete the stored data according to the monitoring result. As a result, a data reproducing device can be obtained, that can effectively realize suppression of reproduction interruption, reduction in reproduction delay, and suppression of the occurrence of steady delay.

Furthermore, the data reproducing device stores received data to monitor the steady delay amount from the storage amount, determines whether to delete the stored data according to the monitoring result, and when the data is to be deleted, determines the data to be deleted based on the data content. As a result, a data reproducing device can be obtained, that can effectively realize suppression of reproduction interruption, reduction in reproduction delay, and suppression of the occurrence of steady delay, while realizing high quality data reproduction.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

1. A data reproducing device capable of performing packet communication, comprising:
a receiving unit that receives data that is any one of audio data and moving image data or both;
a storage unit that stores the data received by the receiving unit;
a monitoring unit that monitors a steady delay amount of the data based on an amount of data stored in the storage unit; and
a determining unit that determines whether to delete data stored in the storage unit based on the steady delay amount monitored by the monitoring unit.

2. The data reproducing device according to claim 1, wherein the monitoring unit monitors the steady delay amount according to the reception timing of the received data.

3. The data reproducing device according to claim 1, wherein the monitoring unit monitors the steady delay amount according to the reproduction timing of the received data.

4. The data reproducing device according to claim 1, further comprising a timer that measures the passage of time, wherein the monitor monitors the steady delay amount according to time information output by the timer.

5. The data reproducing device according to claim 1, wherein the monitoring unit monitors the steady delay amount according to the amount of data stored in the storage unit.

6. The data reproducing device according to claim 1, further comprising a content inspecting unit that inspects the contents of the received data, wherein
when the determining unit determines that the data is to be deleted, the storage unit determines the data to be deleted based on the contents of the received data determined by the content inspecting unit.

7. The data reproducing device according to claim 1, wherein when the determining unit determines that the data is to be deleted, the storage unit collectively deletes the received data in an amount corresponding to the steady delay amount.

8. The data reproducing device according to claim 1, further comprising:
a validity checking unit that checks the validity of packets in the received data; and
a packet aligning unit that aligns the packets based on the check result by the validity checking unit.

9. A method of reproducing data that is any one of audio data and moving image data or both and that is received in packet communication, comprising:
receiving the data;
storaging the received data;
monitoring a steady delay amount of the data based on an amount of data stored; and
determining whether to delete data stored in the storage unit based on the steady delay amount monitored.
